(19) United States
(12) Patent Application Publication
(10) Pub. No.: US 2017/0301820 A1
(43) Pub. Date: Oct. 19, 2017

(54) SOLAR CELL PRODUCTION APPARATUS FOR PROCESSING A SUBSTRATE, AND METHOD FOR PROCESSING A SUBSTRATE FOR THE PRODUCTION OF A SOLAR CELL

(71) Applicant: APPLIED MATERIALS ITALIA S.R.L., San Biagio di Callalta (TV) (IT)

(72) Inventors: Luigi DE SANTI, Spresiano (TV) (IT); Daniele GISLON, Santa Maria Di Sala - Venice (IT); Andrea BACCINI, Mignagola Di Carbonera (TV) (IT); Tommaso VERCESI, Aschaffenburg (DE); Gianfranco PASQUALIN, Spresiano (IT)

(73) Assignees: APPLIED MATERIALS ITALIA S.R.L., San Biagio di Callalta (TV) (IT); APPLIED MATERIALS ITALIA S.R.L., San Biagio di Callalta (TV) (IT)

(21) Appl. No.: 15/122,044

(22) PCT Filed: Dec. 2, 2014
(86) PCT No.: PCT/EP2014/076230

§ 371 Date: Aug. 26, 2016

(51) Int. Cl. H01L 31/18; B41M 3/00; H01L 21/68; H01L 21/66

(52) U.S. Cl. CPC H01L 31/18; H01L 22/10; B41M 3/00; H01L 21/681

(57) ABSTRACT

The present disclosure provides a solar cell production apparatus for processing a substrate. The solar cell production apparatus includes at least one substrate support configured to support the substrate; one or more printing stations configured for forming a printing structure on the substrate positioned on the substrate support; and an inspection system including at least one first camera, wherein the at least one first camera is configured for detecting a position of the printing structure on the substrate positioned on the substrate support while the substrate is passing through a field of view of the at least one first camera.

### TECHNICAL FIELD

Embodiments of the present disclosure relate to a solar cell production apparatus for processing a substrate, and relate to a method for processing a substrate for the production of a solar cell. Embodiments of the present disclosure particularly relate to a solar cell production apparatus for deposition of a material on a substrate, and relate to a method for deposition of a material on a substrate for the production of a solar cell. Embodiments of the present disclosure specifically relate to an apparatus for screen printing on a substrate for the production of a solar cell.

### BACKGROUND OF THE DISCLOSURE

Solar cells are photovoltaic (PV) devices that convert sunlight directly into electrical power. Within this field, it is known to produce solar cells on a substrate such as a crystalline silicon base by means of printing techniques, such as screen printing, achieving on the front surface of the solar cells a structure of selective emitters.

A solar cell production apparatus for manufacturing a solar cell may have a line configuration with a transportation path, wherein a plurality of process stations can be provided along the transportation path. The process stations may include one or more printing stations for deposition of a material on a substrate, inspection stations and alignment stations. During a production process, the substrate may be transported through, and processed in, at least some of the process stations. Transportation of the substrates and processing of the substrates in the various process stations takes time, limiting a production efficiency and throughput of the solar cell production apparatus.

In view of the above, the present disclosure aims at providing a solar cell production apparatus for deposition of a material on a substrate that has an increased production efficiency and/or throughput. It is in particular an object of the present disclosure to provide a solar cell production apparatus for deposition of a material on a substrate that is capable of producing an increased quantity of solar cells.

### SUMMARY OF THE DISCLOSURE

In light of the above, a solar cell production apparatus for processing a substrate, and a method for processing a substrate for the production of a solar cell are provided. Further aspects, advantages, and features of the present disclosure are apparent from the dependent claims, the description, and the accompanying drawings.

According to an aspect of the present disclosure, a solar cell production apparatus for processing a substrate is provided. The apparatus includes at least one substrate support configured to support the substrate; one or more printing stations configured for forming a printing structure on the substrate positioned on the substrate support; and an inspection system including at least one first camera, wherein the at least one first camera is configured for detecting a position of the printing structure on the substrate while the substrate positioned on the substrate support is passing through a field of view of the at least one first camera.

According to another aspect of the present disclosure, a solar cell production apparatus for screen printing on a substrate is provided. The apparatus includes at least one substrate support configured to support the substrate; one or more printing stations configured for depositing a printing structure on the substrate positioned on the substrate support; and an inspection system including at least one matrix camera and at least one linear camera, wherein the at least one linear camera is configured for detecting a position of the printing structure on the substrate, and wherein the at least one matrix camera is configured for detecting a position of the substrate on the substrate support before depositing the printing structure on the substrate, in particular while the substrate positioned on the substrate support is passing through a field of view of the at least one linear camera.

According to still another aspect of the present disclosure, a method for processing a substrate for the production of a solar cell is provided. The method includes forming a printing structure on the substrate positioned on a substrate support; and detecting a position of the printing structure on the substrate by at least one first camera while the substrate is passing through a field of view of the first camera.

According to yet another aspect of the present disclosure, a method for transporting a substrate for the production of a solar cell is provided. The method includes moving the at least one substrate support with respect to a printing device during a printing process, in particular wherein the printing device is fixed in position during the printing process.

Embodiments are also directed at apparatuses for carrying out the disclosed methods and include apparatus parts for performing each described method aspect. These method steps may be performed by way of hardware components, a computer programmed by appropriate software, by any combination of the two or in any other manner. Furthermore, embodiments according to the disclosure are also directed at methods for operating the described apparatus. It includes method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 shows a perspective view of a solar cell production apparatus for processing a substrate according to embodiments disclosed herein;

FIG. 2 shows a perspective view of a solar cell production apparatus for processing a substrate according to further embodiments disclosed herein;

FIG. 3 shows a cross-sectional front view of the solar cell production apparatus of FIG. 2 according to embodiments disclosed herein;

FIG. 4 shows a plan view of the solar cell production apparatus of FIG. 2 according to embodiments disclosed herein;

FIG. 5 shows a side view of the solar cell production apparatus of FIG. 2 according to embodiments disclosed herein;

FIGS. 6A and 6B show perspective views of a substrate support of a solar cell production apparatus according to embodiments disclosed herein;

FIG. 7 shows a perspective view of a solar cell production apparatus for processing a substrate according to further embodiments disclosed herein; and

FIG. 8 shows a flowchart of a method for processing a substrate for production of a solar cell according to embodiments described herein.

### DETAILED DESCRIPTION OF EMBODIMENTS

Reference will now be made in detail to the various embodiments of the disclosure, one or more examples of which are illustrated in the Figures. Within the following description of the drawings, the same reference numbers refer to same components. Generally, only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

According to an aspect of the present disclosure, a solar cell production apparatus for processing a substrate for the production of a solar cell is provided. The apparatus includes at least one substrate support configured to support the substrate; one or more printing stations configured for forming a printing structure on the substrate positioned on the substrate support; and an inspection system including at least one first camera, wherein the at least one first camera is configured for detecting a position of the printing structure on the substrate while the substrate positioned on the substrate support is passing through a field of view of the at least one first camera.

According to some embodiments, the printing structure may include, but is not limited to, at least one of a printing track, such as at least one of a finger and a busbar, a cross, a marker element and a printing structure.

According to some embodiments, the solar cell production apparatus is configured for at least one of screen printing, ink-jet printing and laser processing. In some implementations, the laser processing may include creating holes in the substrate to create a pattern where a printing paste can be deposited for forming the printing structure. According to some embodiments, “laser processing” can also be referred to as “laser printing”.

In some implementations, the at least one first camera includes at least one linear camera or at least one matrix camera. For instance, the at least one first camera can be a single linear camera. In other implementations, the at least one first camera can include a single matrix camera or a system of matrix cameras. As an example, the at least one first camera can include a system of matrix cameras having at least 2 matrix cameras, and specifically having 5 matrix cameras.

The term “field of view” (FOV) as used throughout this application refers to a region that is visible through the first camera at a particular position and orientation in space. Objects outside the FOV when the picture is taken are not recorded in the picture.

In some implementations, the position of the printing structure on the substrate is a position with respect to one or more reference points. The one or more reference points may include, but are not limited to, at least one feature of the substrate, such as an edge or corner of the substrate, and a reference point provided by the solar cell production apparatus, such as a printing head of the one or more printing stations. The one or more reference points may also include one or more fiducials, e.g., if double printing is performed.

According to some implementations, the at least one first camera, e.g., a linear camera, allows for detecting the position of the printing structure on the substrate while the at least one substrate support is moving, e.g., along a transport path or transport track. In other words, the position of the printing structure on the substrate can be detected while the at least one substrate support passes the linear camera, in particular the field of view of the at least one first camera. According to embodiments described herein, the at least one substrate support has not to be stopped for the detection of the position of the printing structure. Further, when the at least one first camera is configured for a quality check of the printing structure (e.g., finger interruption, stain, crack, etc.), the at least one substrate support does not have to be stopped for the quality check.

The solar cell production apparatus according to the embodiments described herein has an increased production efficiency and/or throughput. The solar cell production apparatus is in particular capable of producing an increased quantity of solar cells.

The at least one first camera, e.g., the linear camera, further allows for detecting the position of the printing structure on the substrate with high precision and accuracy. As an example, the at least one first camera can be configured for generating an image having 64 megapixel or more. In particular, the at least one first camera may provide high resolution improving the printing detection and/or a quality check of the printing structure on the substrate. In some embodiments, the solar cell production apparatus is configured as a linear apparatus providing a linear transportation path or linear transportation track for the substrate support. The linear motion of the substrate support allows for the use of e.g. the linear camera with high resolution, improving the printing detection and/or a quality check of the printing structure on the substrate.

A linear camera as understood herein may include a linear sensor array. As an example, the linear sensor array may include a single line of sensors such as photosensors, or three lines for the three colors, namely red, green and blue. The sensors may include CCD (charge-coupled device) sensors. The linear camera may also be referred to as a “line camera”.

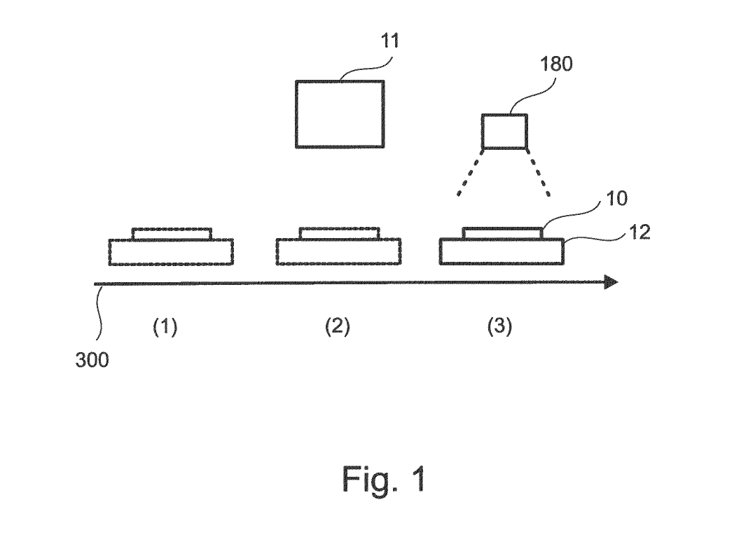

FIG. 1 shows a perspective view of a solar cell production apparatus for processing a substrate according to embodiments disclosed herein. According to some embodiments, the solar cell production apparatus is configured for deposition of a material on a substrate. As an example, the solar cell production apparatus can be configured for screen printing. In other implementations, the solar cell production apparatus can be configured for ink-jet printing or laser processing.

According to an aspect of the present disclosure, the solar cell production apparatus for processing a substrate 10 is provided. The solar cell production apparatus includes at least one substrate support 12 configured to support the substrate 10; one or more printing stations 11 configured for forming a printing structure on the substrate 10 positioned on the substrate support 12; and an inspection system including at least one first camera 180, wherein the at least one first camera 180 is configured for detecting a position of the printing structure on the substrate 10 positioned on the substrate support 12 while the substrate is passing through a field of view of the at least one first camera 180. As an example, the at least one first camera 180 is configured for detecting a position of the printing structure on the substrate 10 while the substrate 10 is moving, e.g., along the horizontal direction or X-direction.

According to some embodiments, which can be combined with other embodiments described herein, the at least one substrate support 12 can be configured to pass through the field of view of the at least one first camera 180 with a speed in a range of 1 to 1000 mm/s, specifically in a range of 100 to 800 mm/s, and more specifically in a range of 300 to 500 mm/s. The at least one substrate support 12 can for example move with a speed of about 400 mm/s through the field of view of the at least one first camera 180.

According to some implementations, the solar cell production apparatus can be configured for transporting the at least one substrate support along a transport path or transport track, wherein the transport path or transport track may extend in a horizontal direction 300. As an example, the transport path or transport track may be a linear transport path or linear transport track, respectively. The one or more printing stations, the at least one first camera of the inspection system and optionally at least one further process station can be arranged along the transport path or transport track. The at least one further process can include at least one of a substrate loading station, a substrate unloading station, a printing station, an alignment station, a buffer station, an inspection station, a heating station, and combinations thereof.

FIG. 1 shows the substrate support 12 in three different positions (1), (2) and (3) along the transport path or transport track. The substrate 10 may be input to the solar cell production apparatus via position (1). In position (2), the at least one substrate support 12 having the substrate 10 positioned thereon is positioned in or at a printing station of the one or more printing stations 11 for forming a printing structure on the substrate 10. The at least one substrate support 12 having the substrate 10 with the printing structure disposed thereon passes position (3) where the at least one first camera 180 is provided, wherein the at least one first camera 180 detects the position of the printing structure on the substrate 10, e.g., while the substrate support is moving.

In some implementations, the at least one camera 180 allows for detecting the position of the printing structure on the substrate while the at least one substrate support is moving, e.g., along the transport path or transport track. The solar cell production apparatus according to the embodiments described herein has an increased production efficiency and/or throughput. Further, the at least one first camera 180 can be a linear camera that allows for detecting the position of the printing structure on the substrate with high precision and accuracy.

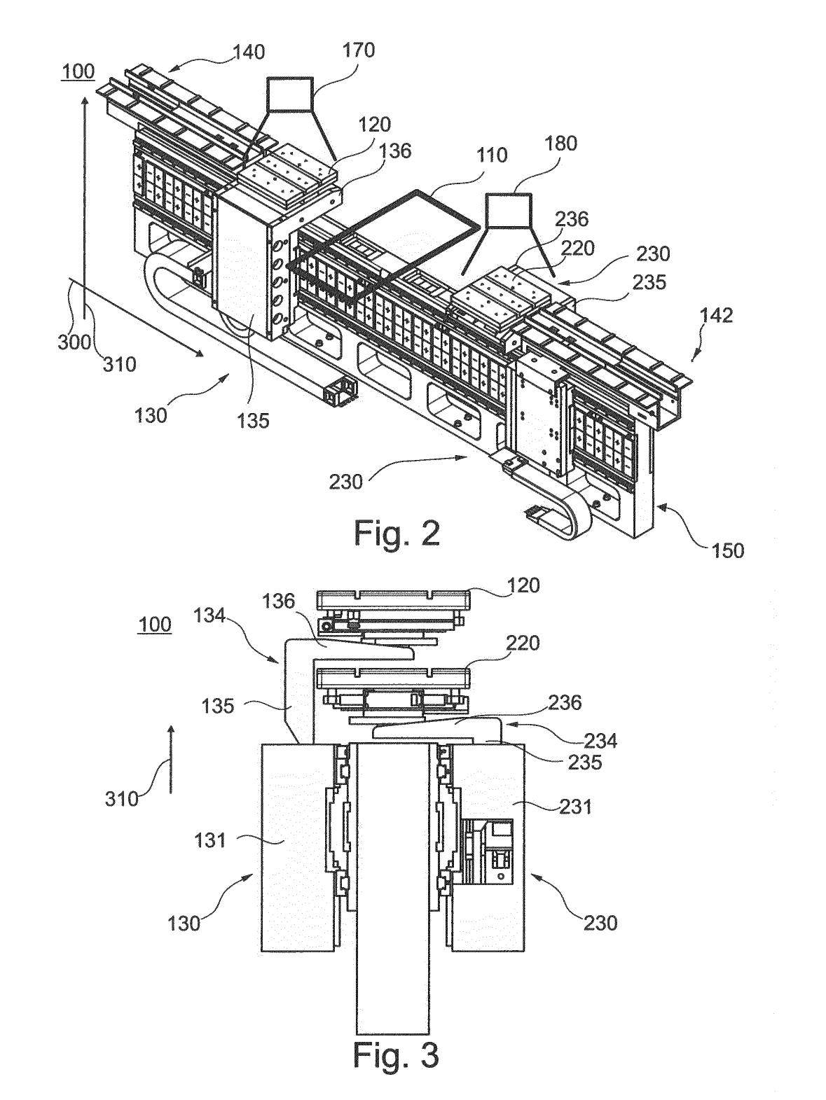

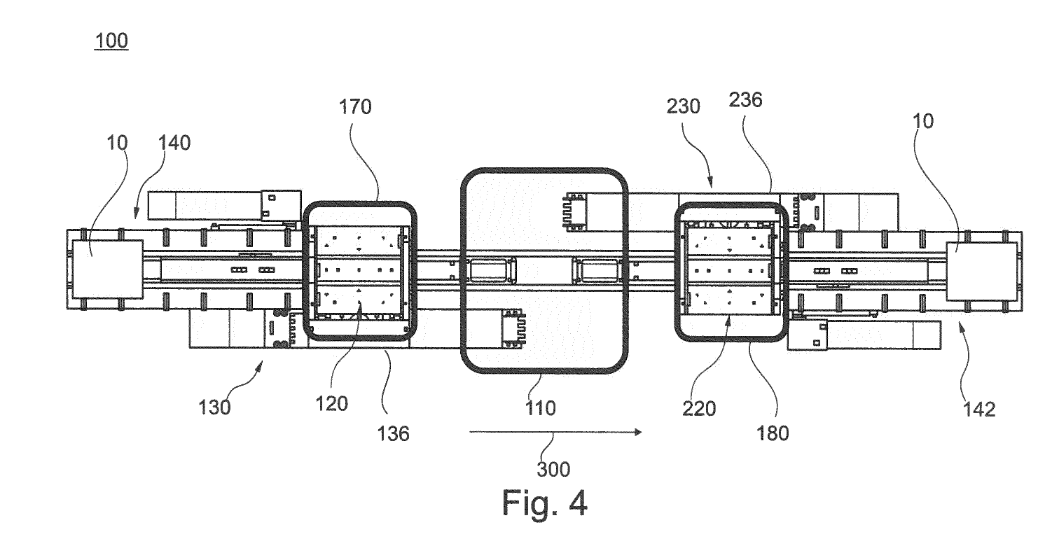

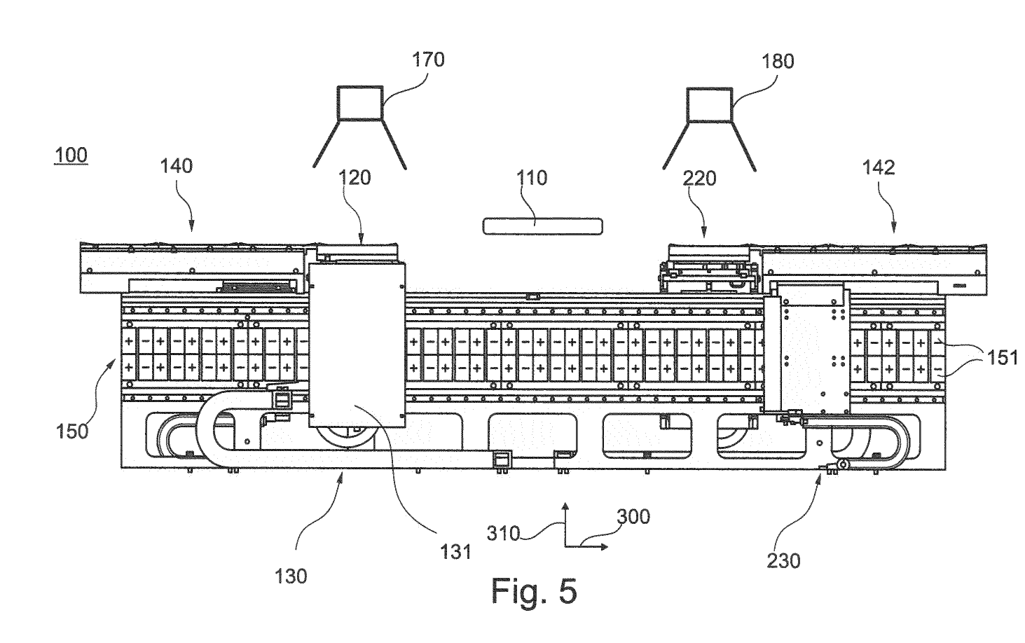

FIG. 2 shows a perspective view of a solar cell production apparatus 100 according to embodiments disclosed herein. FIG. 3 shows a cross-sectional front view of the solar cell production apparatus 100 of FIG. 2. FIG. 4 shows a plan view of the solar cell production apparatus 100 of FIG. 2. FIG. 5 shows a side view of the solar cell production apparatus 100 of FIG. 2.

The solar cell production apparatus 100 as exemplary illustrated includes two or more process stations 110, wherein the two or more process stations 110 include the one or more printing stations; the at least one substrate support, e.g., a first substrate support 120 and a second substrate support 220, configured to support the substrate 10; and the at least one transport device, e.g., a first transport device 130 and a second transport device 230, configured to transport the at least one substrate support in the horizontal direction 300 and in the vertical direction 310 for transporting the at least one substrate support between the two or more process stations 110.

In some implementations, a movement of the at least one substrate support for transporting the at least one substrate support between the two or more process stations has a vertical component and/or a horizontal component. As an example, the movement is a non-vertical upward or downward movement. According to some embodiments, the at least one transport device is configured to simultaneously transport the at least one substrate support in a horizontal direction and in a vertical direction, e.g., to provide the non-vertical upward or downward movement.

By providing substrate supports that can be moved both horizontally and vertically, the substrate supports can be arranged or stacked vertically. In view of this, the apparatus can be compact, requiring less installation space. Further, the vertically arranged substrate supports can simultaneously move from one process station to another process station without interfering with each other, and a throughput of the apparatus can be increased.

The term “vertical direction” or “vertical orientation” is understood to distinguish over “horizontal direction” or “horizontal orientation”. The vertical direction can be substantially parallel to the force of gravity.

According to some embodiments, which can be combined with other embodiments described herein, the horizontal direction 300 and the vertical direction 310 define a substantially vertically oriented two-dimensional plane. In other words, a vector of the horizontal direction 300 and a vector of the vertical direction 310 span the substantially vertically oriented two-dimensional plane, e.g., in Cartesian coordinates.

The term “substantially vertically oriented two-dimensional plane” is understood to distinguish over a “substantially vertically oriented two-dimensional plane”. That is, the “substantially vertically oriented two-dimensional plane” relates to a substantially vertical orientation of the two-dimensional plane, wherein a deviation of a few degrees, e.g. up to 10° or even up to 15°, from an exact vertical orientation is still considered as a “substantially vertical orientation”.

In some implementations, the at least one transport device is configured to transport the at least one substrate support along a transport path lying in the substantially vertically oriented two-dimensional plane.

In some implementations, the solar cell production apparatus 100 can include one or more conveyors, such as a first conveyor 140 and a second conveyor 142. The one or more conveyors can be configured for transferring an unprocessed substrate onto the first substrate support 120 and/or onto the second substrate support 220. Additionally or optionally, the one or more conveyors can be configured for transferring a processed substrate from the first substrate support 120 and/or from the second substrate support 220. As an example, the first conveyor 140 can be an incoming conveyor configured for receiving an unprocessed substrate from an input device (not shown), and can be configured to transfer the unprocessed substrate to the first substrate support 120 and/or the second substrate support 220. The second conveyor 142 can be an outgoing conveyor configured to receive a processed substrate from the first substrate support 120 and/or the second substrate support 220, and can be configured to transfer the processed substrate to a substrate removal device (not shown).

According to some embodiments, which can be combined with other embodiments described herein, the at least one transport device, e.g., the first transport device 130 and the second transport device 230, is configured to transport the at least one substrate support, such as the first substrate support 120 and the second substrate support 220, in the horizontal direction 300 and in the vertical direction 310. According to some embodiments, which can be combined with other embodiments described herein, the horizontal direction 300 and the vertical direction 310 define the substantially vertically oriented two-dimensional plane explained above.

According to some embodiments, which can be combined with other embodiments described herein, the at least one transport device includes a first motor for transporting the at least one substrate support in the vertical direction 310. As an example, the first motor is a linear motor. According to some embodiments, which can be combined with other embodiments described herein, the first motor is a stepper motor, a servo motor or a pneumatic motor. Particularly using a linear motor allows for a fine adjustment of the vertical position of the at least one substrate support.

In some implementations, the solar cell production apparatus 100 includes a connection device configured for connecting the at least one transport device, and specifically the first motor, with the at least one substrate support. The connection device can be included in the at least one transport device. As an example, the solar cell production apparatus 100 can include a first connection device 134 configured for connecting the first transport device 130, and specifically the first motor of the first transport device 130, with the first substrate support 120. Further, the solar cell production apparatus 100 can include a second connection device 234 configured for connecting the second transport device 230, and specifically the second motor of the second transport device 230, with the second substrate support 220.

According to some embodiments, the connection device, such as the first connection device 134 and the second connection device 234, is substantially L-shaped. The substantially L-shaped connection device can include a first connection element extending substantially in the vertical direction 310, and can include a second connection element extending substantially in the horizontal direction 300. As an example, the first connection device 134 can include a first connection element 135 and a second connection element 136. The second connection device 234 can include another first connection element 235 and another second connection element 236. In some implementations, the first connection element can be configured for a connection with the at least one transport device, and the second connection element can be configured for a connection with the at least one substrate support.

The term “extending substantially in the vertical direction” is understood to distinguish over “extending substantially in the horizontal direction”. That is, “extending substantially in the vertical direction” relates to a substantially vertical extension, e.g., of the first connection element, wherein a deviation of a few degrees, e.g. up to 10° or even up to 30°, from an exact vertical extension is still considered as a substantially vertical extension. Similarly, “extending substantially in the horizontal direction” relates to a substantially horizontal extension, e.g., of the second connection element, wherein a deviation of a few degrees, e.g. up to 10° or even up to 30°, from an exact horizontal extension is still considered as a substantially horizontal extension.

According to some embodiments, which can be combined with other embodiments described herein, the at least one transport device includes a second motor 150 for transporting the at least one substrate support in the horizontal direction 300. As an example, the second motor 150 is a linear motor. According to some embodiments, which can be combined with other embodiments described herein, the second motor is a stepper motor, a servo motor or a pneumatic motor. Particularly using a linear motor allows for a fine adjustment of the vertical position of the at least one substrate support.

In some implementations, the at least one transport device includes a static or non-moving portion and a moveable portion, such as a first moveable portion 131 of the first transport device 130 and a second moveable portion 231 of the second transport device 230. As an example, the second motor 150 can include magnets 151 that are fixed in position, and the second motor 150 can include coils that are moving at least horizontally together with the moveable portion of the transport device. As a further example, the moveable portion can include the first motor of the transport device, so that the first motor is moveable along the horizontal direction 300 together with the at least one substrate support.

According to some embodiments, which can be combined with other embodiments described herein, the solar cell production apparatus 100 includes the inspection system having the at least one first camera 180. The inspection system, and in particular the at least one first camera 180, can for example be included in an inspection station.

According to some embodiments, which can be combined with other embodiments described herein, the solar cell production apparatus 100 further includes an alignment system configured for aligning at least one of a position and an angular orientation of the at least one substrate support and/or of at least one printing device (e.g., a printing head), in particular in a horizontal plane. The at least one printing device can be included in the one or more printing stations and can be configured for at least one of screen printing, ink-jet printing and laser processing. The alignment system allows for an adjustment of the position and/or orientation of the substrate e.g. with respect to the printing device, or vice versa, for an alignment of the printed structure with a subsequently printed structure. In particular, the alignment system allows for an alignment so that the structure(s) printed on the substrate can be aligned with respect to the substrate and/or with respect to each other.

According to some embodiments, which can be combined with other embodiments described herein, the alignment system is configured to adjust at least one of the position and the angular orientation of the substrate support and/or of the at least one printing device based on the position of the printing structure detected by the inspection system. As an example, the detected position of the printing structure can be used by the alignment system to align the at least one substrate support and thus the substrate, e.g., with respect to a printing device such as a printing head.

In some embodiments, the alignment system is configured to adjust at least one of the position and the angular orientation of the substrate support and/or of the at least one printing device before forming or printing another printing structure on the substrate. By performing the adjustment before forming or printing another printing structure on the substrate, a subsequently deposited printing structure can be aligned with respect to the printing structure that is already provided on the substrate. A quality of the produced solar cell can be increased.

According to some embodiments, which can be combined with other embodiments described herein, the inspection system is configured for a closed loop or feedback control. As an example, the alignment system is configured to adjust at least one of the position and the angular orientation of a subsequent substrate support based on the detected position of the printing structure on the substrate on the substrate support. By adjusting the position and/or the angular orientation of the subsequent substrate support, an accuracy of the position of one or more printing structures on the subsequent substrate can be improved.

The inspection system of the present disclosure can improve an alignment or positioning of one or more printing structures on the substrate, and/or can improve an alignment of one or more printing structures on a subsequently processed substrate, in particular by using the closed loop or feedback control.

In some implementations, the inspection system is configured for a quality check of the printing structure on the substrate. As an example, the inspection system may use images or data taken by the at least one first camera 180 for the quality check of the printing structure on the substrate. In other words, the at least one first camera 180 may be used for multiple tasks, such as positioning of the at least one substrate support and the quality check.

In some implementations, the alignment system is configured to position the at least one substrate support and/or the at least one printing device in the X-direction and the Y-direction, and/or is configured to adjust the angular orientation of the at least one substrate support and/or the at least one printing device to a target orientation. The X-direction and the Y-direction may be the X-direction and the Y-direction of a Cartesian coordinate system, and may in particular define the horizontal plane. The angular orientation may refer to an angular orientation of the at least one substrate support with respect to a target such as the printing device. As an example, the angular orientation can be defined as an angle (e.g., theta) between a first reference line at the substrate support and a second reference line at the target such as the printing device.

According to some embodiments, the alignment system can include one or more actuators for aligning the position and/or the angular orientation of the at least one substrate support and/or the at least one printing device in the horizontal plane. The one or more actuators can include a stepper motor, a pneumatic motor and/or a server motor. As an example, the alignment system can include three actuators, e.g., a first actuator for moving or positioning the substrate support and/or the at least one printing device in X-direction, a second actuator for moving or positioning the substrate support and/or the at least one printing device in Y-direction, and a third actuator for angularly moving or positioning the substrate support and/or the at least one printing device. In some implementations, the first actuator and the second actuator can be linear actuators, and/or the third actuator can be a rotary actuator.

According to some embodiments, which can be combined with other embodiments described herein, the alignment system is included in the transport device and/or in the at least one substrate support.

According to some embodiments, which can be combined with other embodiments described herein, the inspection system further includes at least one second camera 170. The at least one second camera 70 can be a matrix camera. As an example, the at least one second camera 170 is configured for detecting a position of the substrate on the substrate support before forming the printing structure on the substrate. In some implementations, the at least one second camera 170 can have a resolution of at least 1 megapixel, and can specifically have a resolution of at least 2 megapixel. The at least one second camera 170 can include a single matrix camera or a system of matrix cameras. As an example, the at least one second camera 170 can include a system of matrix cameras having at least 2 matrix cameras, and specifically having 3, 4 or 5 matrix cameras.

According to some embodiments, which can be combined with other embodiments described herein, the solar cell production apparatus 100 further includes a transport path or transport track configured for transportation of the at least one substrate support, wherein the at least one second camera 170, at least one of the one or more printing stations and the at least one first camera 180 are sequentially arranged along the transport path or transport track, in particular in this order. The transport path or transport track may be a linear transport path or linear transport track, respectively. In some implementations, the transport path or transport track may extend in the horizontal direction 300.

According to some embodiments, which can be combined with other embodiments described herein, the at least one second camera 170, the one or more printing stations and the at least one first camera 180 are sequentially or successively arranged, e.g., along the transport path or transport track. As an example, the at least one second camera 170 can be included in an alignment station positioned upstream from the one or more printing stations, and the at least one first camera 180 can be included in an inspection station positioned downstream from at least one printing station of the one or more printing stations.

In some implementations, the printing device and the at least one substrate support are moveable with respect to each other for printing. In particular, the printing device at least one substrate support are moveable with respect to each other in the horizontal direction 300, e.g., the X-direction. As an example, the printing device is moveable in at least one direction such as the X-direction along the at least one substrate support for printing. In such a case, the at least on substrate support can hold its position, i.e., the at least one substrate support is not moving during printing. In another example, the printing device is fixed in position while the at least one substrate support is configured to move e.g. in X-direction with respect to the printing device for printing. In such a case, the printing device can hold its position, i.e., the printing device is not moving during printing, but the at least one substrate support is moving during printing. The printing device can be configured for screen printing, ink-jet printing or laser processing.

In some implementations, the transport path or transport track is configured for transportation of the substrate support between two or more process stations as previously described. As an example, the transport path or transport track can be included in the at least one transport device.

According to some embodiments, which can be combined with other embodiments described herein, the two or more process stations are selected from the group including: a substrate loading station, a substrate unloading station, a printing station, an alignment station, a buffer station, an inspection station, a heating station, and combinations thereof.

According to some embodiments, which can be combined with other embodiments described herein, the apparatus is configured for screen printing. As an example, the printing station may include one or more printing heads and one or more screen devices for screen printing of patterns such as fingers and busbars on the substrate for the production of a solar cell. In some embodiments, the screen device defines a pattern or features corresponding to a structure to be printed on the substrate, wherein the pattern or features may include at least one of holes, slots, incisions or other apertures.

In some implementations, the apparatus includes a squeegee, wherein the screen device is provided between the substrate support and the squeegee. The squeegee can be configured for printing, and in particular screen printing. In some embodiments, the squeegee and the screen device are moveable with respect to each other for printing. As an example, the squeegee is moveable in at least one direction along the screen device for printing. In such a case, the at least on substrate support can hold its position, i.e., the at least one substrate support is not moving during printing. In another example, the squeegee is fixed in position while the at least one substrate support is configured to move e.g. in X-direction with respect to the squeegee for printing. In such a case, the squeegee can hold its position, i.e., the squeegee is not moving during printing, but the at least one substrate support is moving during printing.

According to another aspect of the present disclosure a solar cell production apparatus for screen printing on a substrate is provided. The apparatus includes at least one substrate support configured to support the substrate; one or more printing stations configured for depositing a printing structure on the substrate; and an inspection system including a matrix camera and a linear camera, wherein the linear camera is configured for detecting a position of the printing structure on the substrate, and wherein the matrix camera is configured for detecting a position of the substrate on the substrate support before depositing the printing structure on the substrate.

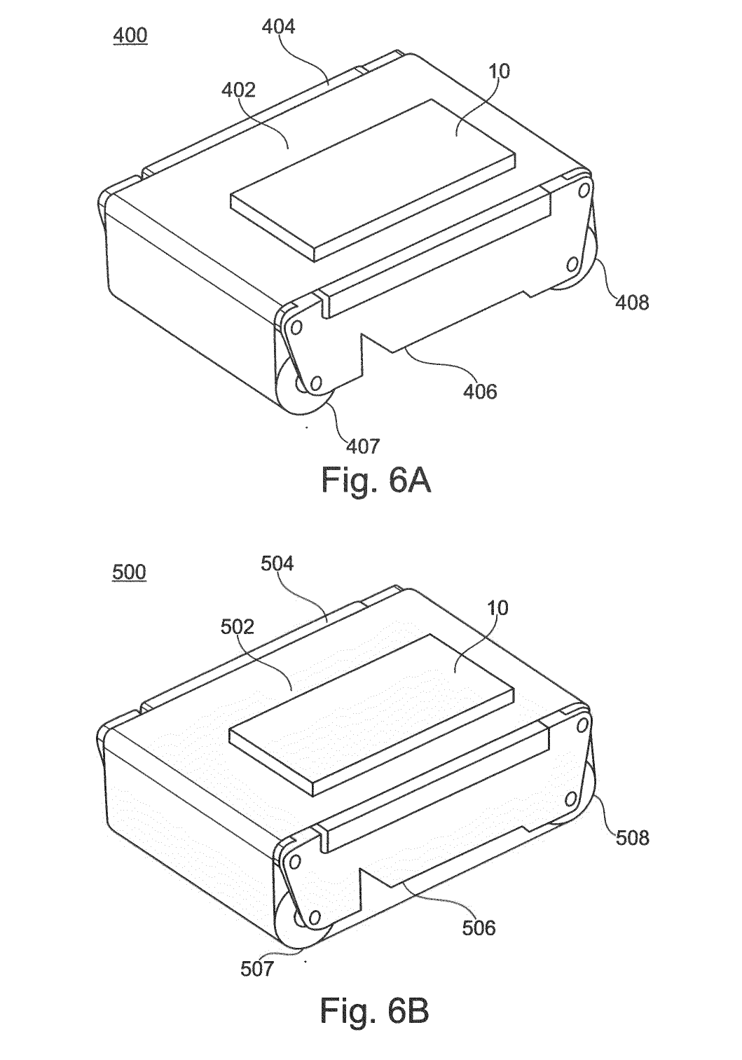

FIG. 6A shows a perspective view of a substrate support 400 according to embodiments disclosed herein. According to some embodiments, the substrate support can also be referred to as “processing nest”.

In some implementations, the substrate support 400 includes a conveyor device 406 having a feed roll 407 and a reception roll 408. The feed roll 407 and the reception roll 408 are configured to feed and retain a material 402 positioned on a surface 404 of the substrate support 400. According to some embodiments, the material 402 can be periodically removed and replaced.

According to some embodiments, which can be combined with other embodiments described herein, the substrate support 400 includes at least one suction device (not shown) configured for holding the substrate 10 on the substrate support 400. As an example, the material 402 can be a porous material that allows the substrate 10 disposed on one side of the material 402 to be held to the surface 404 by a vacuum applied to the opposing side of the material 402 e.g. by vacuum ports formed in the surface 404. In some implementations, a vacuum is created by use of a vacuum source (not shown) coupled to the ports in the surface 404.

FIG. 6B shows a perspective view of a substrate support 500 according to further embodiments disclosed herein. According to some embodiments, the substrate support can also be referred to as “processing nest”. A conveyor device 506 of the substrate support 500 is configured as a continuous conveyor system having one or more first rollers 508 and one or more second rollers 507 for feeding the material 502 positioned across the surface 504. The surface 504 can support the substrate 10 and the material 502 during the processing, e.g., at a process station such as a printing station.

According to some embodiments, which can be combined with other embodiments described herein, the substrate support 500 includes at least one suction device configured for holding the substrate 10 on the substrate support 500. As an example, the material 502 can be a porous material that allows the substrate 10 disposed on one side of the material 502 to be held to the surface 504 by a vacuum applied to the opposing side of the material 502, e.g., by vacuum ports formed in the surface 504. In some implementations, a vacuum is created by use of a vacuum source (not shown) coupled to the ports in the surface 504. According to some embodiments, the material 502 is cleaned as it is fed by the one or more feed rollers 508.

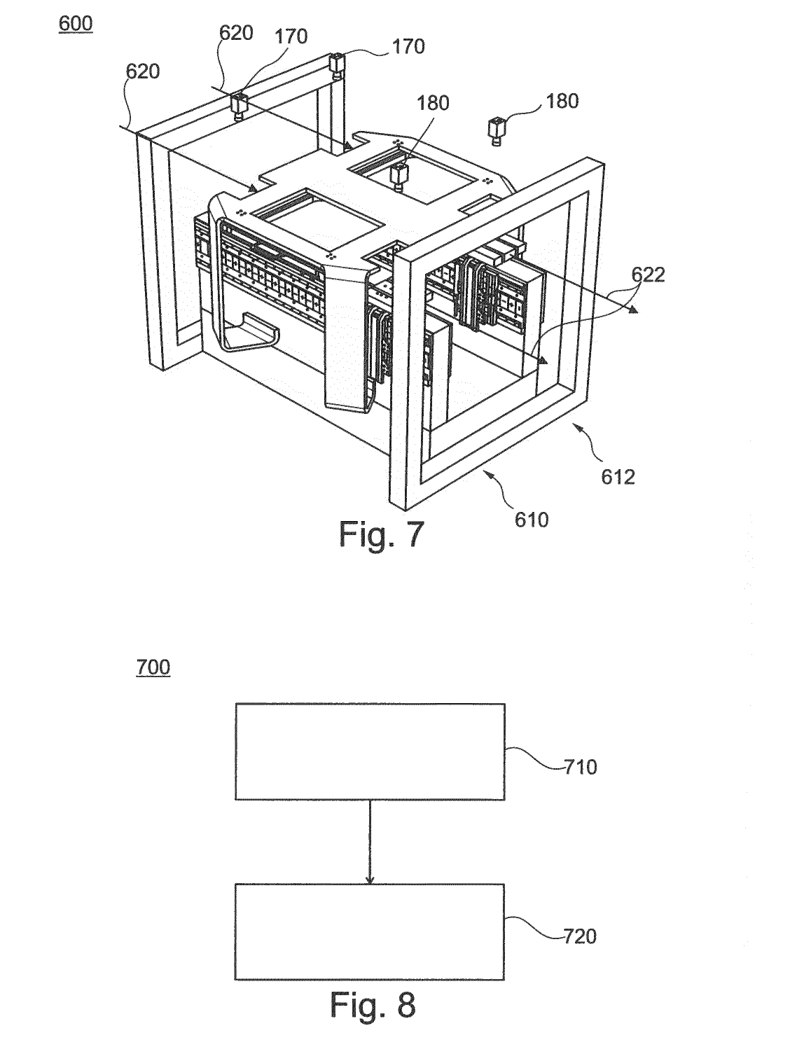

FIG. 7 shows a perspective view of a system 600 for printing on a substrate for the production of a solar cell according to embodiments disclosed herein.

The system 600 has a dual-line configuration and includes a first apparatus 610 for printing on a substrate for the production of a solar cell and a second apparatus 612 for printing on a substrate for the production of a solar cell.

In some implementations, the first apparatus 610 and the second apparatus 612 are arranged in parallel and provide two production lines for the production of solar cells. The first apparatus 610 and the second apparatus 612 can be operated independently from each other so that each of the first apparatus 610 and the second apparatus 612 is able to perform at least a part of a solar cell production process, and particularly a complete solar cell production process.

In other examples, the first apparatus 610 and the second apparatus 612 can be operated in cooperation so that the first apparatus 610 and the second apparatus 612 together perform the solar cell production process. As an example, the first apparatus 610 and the second apparatus 612 can include different process stations, wherein the at least one substrate support can be transferred from the first apparatus 610 to the second apparatus 612 and from the second apparatus 612 to the first apparatus 610.

The system 600 has an input 620 for inputting unprocessed substrates into the system 600. The input 620 can be a double-line input for inputting substrates in the first apparatus 610 and the second apparatus 612, respectively. The system 600 has an exit 622 for removing processed substrates out of the system. The exit 622 can be a double-line exit for removing substrate from the first apparatus 610 and the second apparatus 612, respectively.

According to some embodiments, the first apparatus 610 and/or the second apparatus 612 includes the inspection system having the at least one second camera 170, such as a matrix camera. The at least one second camera 170 can be included in an alignment station at or near to the input 620. The at least one second camera 170 can be used for alignment as described above with reference to FIGS. 2 to 5. According to some embodiments, the first apparatus 610 and/or the second apparatus 612 includes the inspection system having the at least one first camera 180, such as a linear camera, at or near to the exit 622. The at least one first camera 180 can be used for alignment and/or for quality inspection, e.g., of the printed structures, as described above with reference to FIGS. 1 to 5.

FIG. 8 shows a flowchart of a method 700 for processing a substrate for the production of a solar cell according to embodiments described herein.

According to an aspect of the present disclosure, the method 700 includes forming a printing structure on the substrate positioned on a substrate support (block 710); and detecting a position of the printing structure on the substrate by at least one first camera while the substrate is passing through a field of view of the first camera (block 720).

As an example, before printing, the inspection system, e.g., the matrix camera detects the position of the substrate (e.g., a wafer) using for example an edge or a corner of the substrate or fiducials (if double printing is performed). After printing, the at least one substrate support moves e.g. using a linear motor. According to some embodiments, which can be combined with other embodiments described herein, the at least one substrate support can be configured to move with a speed in a range of 1 to 1000 mm/s, specifically in a range of 100 to 800 mm/s, and more specifically in a range of 300 to 500 mm/s. The at least one substrate support can for example move with a speed of about 400 mm/s. During the motion, the at least one first camera, such as the linear camera, detects the position of the printing structure, e.g., the coordinates, and an offset (e.g., X-Y-theta position) to be applied to the at least one substrate support and/or the at least one printing device for aligning or centering a next printing structure is calculated. The calculated offset can be different for different substrate supports.

In some implementations, the method can further include adjusting at least one of the position and the angular orientation of the substrate support and/or at least one printing device based on the position of the printing detected by the at least one first camera before depositing another printing structure on the substrate. According to some further embodiments, the method includes adjusting at least one of the position and the angular orientation of a subsequent substrate support based on the detected position of the printing structure on the substrate on the substrate support using feed-back control.

According to some embodiments, the method further includes moving the substrate support with respect to a printing device during a printing process, in particular wherein the printing device is fixed in position during the printing process. As an example, the printing device can be a printing device for screen printing, such as a squeegee, a printing device for ink-jet printing, or a printing device for laser printing. The printing process can be a screen printing process, an ink-jet printing process or a laser printing process. In some implementations, the moving the at least one substrate support with respect to the printing device includes moving the at least one substrate support in the horizontal direction, e.g., the X-direction. By moving the at least one substrate support during the printing process, a process time for manufacturing e.g. a solar cell can be reduced.

According to some embodiments, the method uses the solar cell production apparatus according to the embodiments described herein.

According to embodiments described herein, the method for transporting a substrate for the production of a solar cell can be conducted by means of computer programs, software, computer software products and the interrelated controllers, which can have a CPU, a memory, a user interface, and input and output means being in communication with the corresponding components of the apparatus for processing a large area substrate.

The solar cell production apparatus according to the embodiments described herein has an increased production efficiency and/or throughput. Further, the linear camera allows for detecting the position of the printing structure on the substrate with high precision and accuracy.

While the foregoing is directed to embodiments of the disclosure, other and further embodiments of the disclosure may be devised without departing from the basic scope thereof, and the scope thereof is determined by the claims that follow.

1. A solar cell production apparatus for processing a substrate, comprising:
at least one substrate support configured to support the substrate;
one or more printing stations configured for forming a printing structure on the substrate positioned on the substrate support; and
an inspection system including at least one first camera, wherein the at least one first camera is configured for detecting a position of the printing structure on the substrate while the substrate positioned on the substrate support is passing through a field of view of the at least one first camera.

2. The apparatus of claim 1, wherein the at least one first camera includes at least one linear camera or at least one matrix camera.

3. The apparatus of claim 1, including:
two or more process stations including the one or more printing stations; and
at least one transport device configured to transport the at least one substrate support in a horizontal direction and in a vertical direction for transporting the at least one substrate support between the two or more process stations.

4. The apparatus of one of claim 1, wherein the inspection system is configured for a quality check of the printing structure on the substrate.

5. The apparatus of one of claim 1, further including a printing device and an alignment system configured to align at least one of a position and an angular orientation of at least one of the substrate support and the printing device.

6. The apparatus of claim 5, wherein the alignment system is configured to adjust at least one of the position and the angular orientation of at least one of the substrate support and the printing device based on the position of the printing structure detected by the inspection system.

7. The apparatus of claim 5, wherein the alignment system is configured to adjust at least one of the position and the angular orientation of at least one of the substrate support and the printing device before forming another printing structure on the substrate.

8. The apparatus of claim 6, wherein the alignment system is configured to adjust at least one of the position and the angular orientation of a subsequent substrate support based on the detected position of the printing structure on the substrate on the substrate support.

9. The apparatus of claim 1, wherein the inspection system further includes at least one second camera.

10. The apparatus of claim 9, wherein the at least one second camera is configured for detecting a position of the substrate on the substrate support before forming the printing structure on the substrate.

11. The apparatus of claim 9, further including a transport track configured for transportation of the substrate support, wherein the at least one second camera, at least one of the one or more printing stations, and the at least one first camera are sequentially arranged along the transport track.

12. The apparatus of one of claim 1, wherein the apparatus is configured for at least one of screen printing, ink-jet printing, and laser processing.

13. A method for processing a substrate for the production of a solar cell, comprising:
forming a printing structure on the substrate positioned on a substrate support; and
detecting a position of the printing structure on the substrate by at least one first camera while the substrate positioned on the substrate support is passing through a field of view of the at least one first camera.

14. The method of claim 13, further including at least one of:
adjusting at least one of the position and the angular orientation of at least one of the substrate support and a printing device based on the position of the printing detected by the at least one first camera before forming another printing structure on the substrate; and
adjusting at least one of the position and the angular orientation of a subsequent substrate support based on the detected position of the printing structure on the substrate on the substrate support using feed-back control.

15. The method of claim 13, further including: moving the substrate support with respect to a printing device during a printing process.

16. The apparatus of claim 2, wherein the inspection system is configured for a quality check of the printing structure on the substrate.

17. The apparatus of claim 6, wherein the alignment system is configured to align at least one of a position and an angular orientation of at least one of the substrate support and the printing device in a horizontal plane.

18. The apparatus of claim 11, wherein the at least one second camera is a matrix camera.

19. The apparatus of claim 11, further including a transport track configured for transportation of the substrate support, wherein the at least one second camera, at least one of the one or more printing stations and the at least one first camera are sequentially arranged along the transport track.

20. The apparatus of claim 19, wherein the printing device is fixed in position during a printing process.
